(19) United States
(12) Patent Application Publication
(10) Pub. No.: US 2003/0157760 A1
(43) Pub. Date: Aug. 21, 2003

(54) Deposition of tungsten films for dynamic random access memory (DRAM) applications

(75) Inventors: Ming Xi, Milpitas, CA (US); Soonil Hong, Mountain View, CA (US); Hyungsuk A. Yoon, Santa Clara, CA (US); Michael X. Yang, Palo Alto, CA (US); Hui Zhang, Santa Clara, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/082,048

(22) Filed: Feb. 20, 2002

(51) Int. Cl. H01L 21/8238

(52) U.S. Cl. 438/200

(57) ABSTRACT

A method of tungsten deposition for dynamic random access memory (DRAM) applications is described. The DRAM devices typically include two electrodes separated by a dielectric material. At least one of the two electrodes comprises a tungsten-based material. The tungsten-based material may be formed using a cyclical deposition technique. Using the cyclical deposition technique, the tungsten-based material is formed by alternately adsorbing a tungsten-containing precursor and a reducing gas on a structure.

### BACKGROUND OF THE DISCLOSURE

1. Field of the Invention

Embodiments of the present invention generally relate to a method of tungsten film deposition and, more particularly to a method of tungsten film deposition using cyclical deposition techniques for dynamic random access memory (DRAM) applications.

2. Description of the Related Art

Dynamic random access memory (DRAM) integrated circuits are commonly used for storing data in a digital computer. Currently available DRAMs may include over 16 million memory cells fabricated on a single silicon chip, wherein each memory cell typically comprises a single transistor coupled to a micron or sub-micron sized capacitor. In operation, each capacitor may be individually charged or discharged in order to store one bit of information. To facilitate construction of 64 Mbit (Megabit), 256 Mbit, 1 Gbit (Gigabit) and larger DRAMs, smaller memory cells with smaller capacitor structures are needed. One limitation to reducing the size of memory cells is that the capacitors must have sufficient capacitance for reliable information storage ability.

Three-dimensional capacitors, such as trench capacitors and crown capacitors, are types of capacitor structures being explored to increase the charge storage capabilities per the surface area of semiconductor substrates. In general, three-dimensional capacitors comprise non-planar electrodes, which have increased surface area as well as increased capacitance in comparison to planar electrodes. FIG. 1 is a schematic cross-sectional view of a prior art three-dimensional trench capacitor 2. The trench capacitor 2 is formed in a trench 4 defined vertically into the surface of a silicon substrate 6. An insulating layer 7 comprising a dielectric material is formed conformably along the sidewalls 2S of the trench 2 with a polysilicon layer 8 formed thereover so as to fill the trench 4. The silicon substrate 6 acts as a first electrode and the polysilicon layer 8 acts as a second electrode in the three-dimensional trench capacitor 2.

Since the trench capacitor 2 includes non-planar electrodes, such a capacitor structure occupies a smaller surface area of the substrate as compared to a planar capacitor structure (not shown). Thus, increased numbers of trench capacitors may be formed on the substrate as compared to planar capacitors, advantageously increasing the charge storage capabilities per the surface area of the semiconductor substrate.

The capacitance of a trench capacitor 2 may be increased as the depth of the trench 4 is increased. The capacitance increase is due to the increased surface area of the first and second electrodes. Therefore, it is desirable to form trench capacitors in trenches 4 with high aspect ratios (e.g., aspect ratios greater than about 10:1) to increase the surface areas of the first and second electrodes. The term aspect ratio as used herein refers to the height of the trench divided by its width.

However, conventional deposition techniques such as, for example, physical vapor deposition (PVD) and chemical vapor deposition (CVD) are inadequate for depositing material conformably over trench structures having openings less than about 0.2 μm (micrometers) and aspect ratios greater than about 10:1. Conventional physical vapor deposition (PVD) techniques as well as chemical vapor deposition (CVD) techniques tend to have increased material deposition on the top edges of the high aspect ratio trench openings resulting in the closing off of the opening and the formation of a void therein.

Therefore, a need exists for a method of forming three-dimensional capacitors that overcome the above drawbacks.

### SUMMARY OF THE INVENTION

A method of tungsten deposition for dynamic random access memory (DRAM) applications is described. The DRAM devices typically include two electrodes separated by a dielectric material. At least one of the two electrodes comprises a tungsten-based material. The tungsten-based material may be formed using a cyclical deposition technique. Using the cyclical deposition technique, the tungsten-based material is formed by alternately adsorbing a tungsten-containing precursor and a reducing gas on a substrate.

Three-dimensional capacitor structures such as for example, trench capacitors and crown capacitors, comprising at least one electrode formed of a tungsten-based material may be formed using such cyclical deposition techniques. In one embodiment, a preferred process sequence for fabricating a trench capacitor includes providing a substrate having trenches defined therein. The trenches include a first electrode and a dielectric material conformably deposited along the sidewalls of the trenches. The trench capacitor structure is completed by depositing a second electrode comprising a tungsten-based material on the dielectric material in the trenches. The tungsten-based material is formed using cyclical deposition techniques by alternately adsorbing a tungsten-containing precursor and a reducing gas on the substrate.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a schematic cross-sectional view of a prior art three-dimensional trench capacitor;

FIG. 2 depicts a schematic cross-sectional view of a process chamber that can be used for the practice of embodiments described herein;

FIG. 3 illustrates a process sequence for the formation of a tungsten-based material using cyclical deposition techniques according to one embodiment described herein;

FIG. 4 illustrates a process sequence for the formation of a tungsten-based material using cyclical deposition techniques according to an alternate embodiment described herein;

FIGS. 5A-5G depict cross-sectional views of substrates at different stages of trench capacitor fabrication sequences; and

FIGS. 6A-6B depict cross-sectional views of a substrate at different stages of a crown capacitor fabrication sequence.

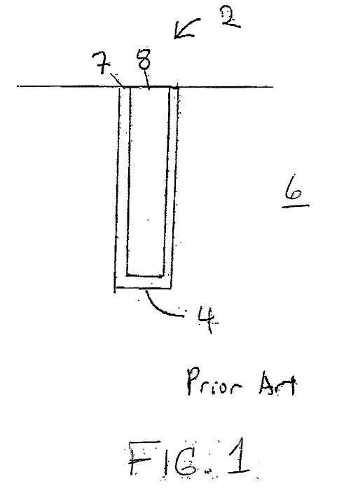

### DETAILED DESCRIPTION

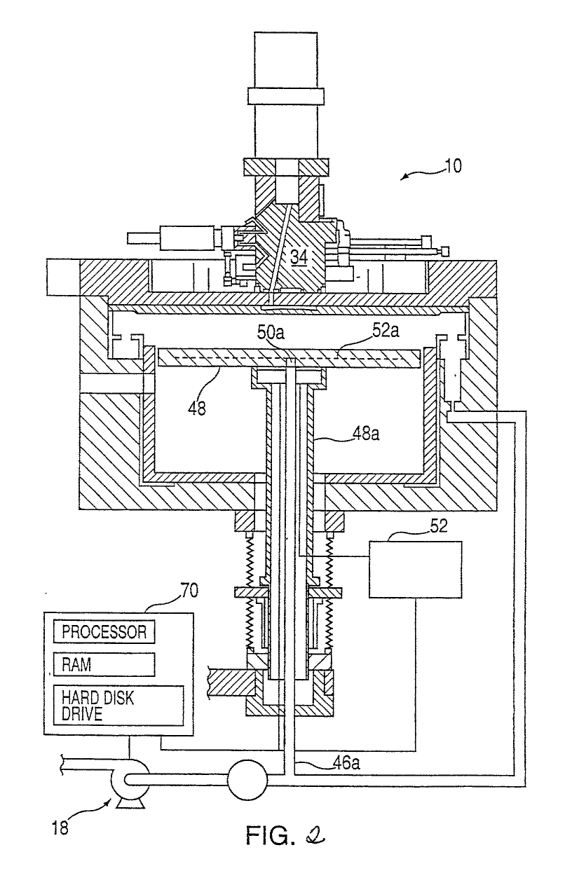

FIG. 2 depicts a schematic cross-sectional view of a process chamber 10 that can be used to perform integrated circuit fabrication in accordance with embodiments described herein. The process chamber 10 generally houses a wafer support pedestal 48, which is used to support a substrate (not shown). The wafer support pedestal 48 is movable in a vertical direction inside the process chamber 10 using a displacement mechanism 48a.

Depending on the specific process, the substrate can be heated to some desired temperature prior to or during deposition. For example, the wafer support pedestal 48 may be heated using an embedded heater element 52a. The wafer support pedestal 48 may be resistively heated by applying an electric current from an AC power supply 52 to the heater element 52a. The substrate (not shown) is, in turn, heated by the pedestal 48. Alternatively, the wafer support pedestal 48 may be heated using radiant heaters such as, for example, lamps.

A temperature sensor 50a, such as a thermocouple, is also embedded in the wafer support pedestal 48 to monitor the temperature of the pedestal 48 in a conventional manner. The measured temperature is used in a feedback loop to control the AC power supply 52 for the heating element 52a, such that the substrate temperature can be maintained or controlled at a desired temperature which is suitable for the particular process application.

A vacuum pump 18 is used to evacuate the process chamber 10 and to maintain the pressure inside the process chamber 10. A gas manifold 34, through which process gases are introduced into the process chamber 10, is located above the wafer support pedestal 48. The gas manifold 34 is connected to a gas panel (not shown), which controls and supplies various process gases to the process chamber 10.

Proper control and regulation of the gas flows to the gas manifold 34 are performed by mass flow controllers (not shown) and a microprocessor controller 70. The gas manifold 34 allows process gases to be introduced and uniformly distributed in the process chamber 10. Additionally, the gas manifold 34 may optionally be heated to prevent condensation of the any reactive gases within the manifold.

The gas manifold 34 includes a plurality of electronic control valves (not shown). The electronic control valves as used herein refer to any control valve capable of providing rapid and precise gas flow to the process chamber 10 with valve open and close cycles of less than about 1-2 seconds, and more preferably less than about 0.1 second.

The microprocessor controller 70 may be one of any form of general purpose computer processor (CPU) that can be used in an industrial setting for controlling various chambers and sub-processors. The computer may use any suitable memory, such as random access memory, read only memory, floppy disk drive, hard disk, or any other form of digital storage, local or remote. Various support circuits may be coupled to the CPU for supporting the processor in a conventional manner. Software routines as required may be stored on the memory or executed by a second CPU that is remotely located.

The software routines are executed to initiate process recipes or sequences. The software routines, when executed, transform the general purpose computer into a specific process computer that controls the chamber operation so that a chamber process is performed. For example, software routines may be used to precisely control the activation of the electronic control valves for the execution of process sequences according to the present invention. Alternatively, the software routines may be performed in hardware, as an application specific integrated circuit or other type of hardware implementation, or a combination of software or hardware.

Tungsten Layer Formation

A method of tungsten deposition for capacitor structure applications is described. The tungsten is deposited using a cyclical deposition technique by alternately adsorbing a tungsten-containing precursor and a reducing gas on a structure. The cyclical deposition techniques employed for the tungsten deposition provides conformal coverage on structures having aggressive geometries such as structures having openings less than about 0.2 μm (micrometers) or aspect ratios greater than about 10:1. Examples of structures having such aggressive geometries include three-dimensional capacitors such as, for example, trench capacitors and crown capacitors.

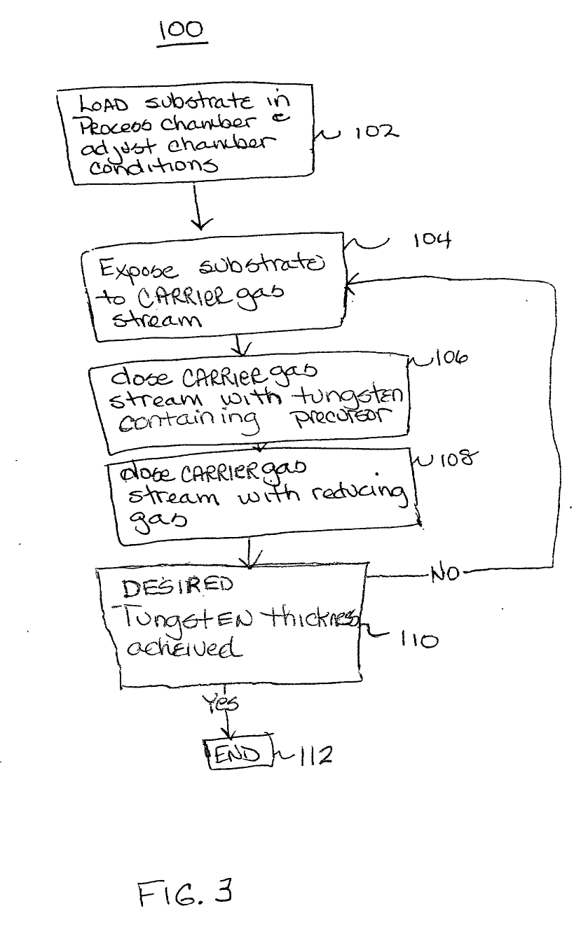

FIG. 3 illustrates an embodiment of a process sequence 100 according to the present invention detailing the various steps used for the deposition of the tungsten layer utilizing a constant carrier gas flow. These steps may be performed in a process chamber similar to that described above with reference to FIG. 2. As shown in step 102, a substrate is provided to the process chamber. The substrate may be for example, a silicon substrate ready for electrode deposition during a DRAM fabrication process. The process chamber conditions such as, for example, the temperature and pressure are adjusted to enhance the adsorption of the process gases on the substrate. In general, for tungsten layer deposition, the substrate should be maintained at a temperature between about 200° C. and 400° C. at a process chamber pressure of between about 1 torr and about 10 torr.

In one embodiment where a constant carrier gas flow is desired, a carrier gas stream is established within the process chamber as indicated in step 104. Carrier gases may be selected so as to also act as a purge gas for removal of volatile reactants and/or by-products from the process chamber. Carrier gases such as, for example, helium (He), argon (Ar), nitrogen (N₂) and hydrogen (H₂), and combinations thereof, among others may be used.

Referring to step 106, after the carrier gas stream is established within the process chamber, a pulse of a tungsten-containing precursor is added to the carrier gas stream. The term pulse as used herein refers to a dose of material injected into the process chamber or into the constant carrier gas stream. The pulse of the tungsten-containing precursor lasts for a predetermined time interval.

The time interval for the pulse of the tungsten-containing precursor is variable depending upon a number of factors such as, for example, the volume capacity of the process chamber employed, the vacuum system coupled thereto and the volatility/reactivity of the reactants used. For example, (1) a large-volume process chamber may lead to a longer time to stabilize the process conditions such as, for example, carrier/purge gas flow and temperature requiring a longer pulse time; (2) a lower flow rate for the process gas may also lead to a longer time to stabilize the process conditions requiring a longer pulse time; and (3) a lower chamber pressure means that the process gas is evacuated from the process chamber more quickly requiring a longer pulse time. In general, the process conditions are advantageously selected so that a pulse of the tungsten-containing precursor provides a sufficient amount of precursor so that at least a monolayer of the tungsten-containing precursor is adsorbed on the substrate. Thereafter, excess tungsten-containing precursor remaining in the chamber may be removed from the process chamber by the constant carrier gas stream in combination with the vacuum system.

In step 108, after the excess tungsten-containing precursor has been removed from the process chamber by the constant carrier gas stream, a pulse of a reducing gas is added to the carrier gas stream. The pulse of the reducing gas also lasts for a predetermined time interval that is variable as described above with reference to the tungsten-containing precursor. In general, the time interval for the pulse of the reducing gas should be long enough for adsorption of at least a monolayer of the reducing gas on the tungsten-containing precursor. Thereafter, excess reducing gas remaining in the chamber may be removed therefrom by the constant carrier gas stream in combination with the vacuum system.

Steps 104 through 108 comprise one embodiment of a deposition cycle for tungsten. For such an embodiment, a constant flow of the carrier gas is provided to the process chamber modulated by alternating periods of pulsing and non-pulsing where the periods of pulsing alternate between the tungsten-containing precursor and the reducing gas along with the carrier gas stream, while the periods of non-pulsing include only the carrier gas stream.

The time interval for each of the pulses of the tungsten-containing precursor and the reducing gas may have the same duration. That is the duration of the pulse of the tungsten-containing precursor may be identical to the duration of the pulse of the reducing gas. For such an embodiment, a time interval (T₁) for the pulse of the tungsten-containing precursor is equal to a time interval (T₂) for the pulse of the reducing gas.

Alternatively, the time interval for each of the pulses of the tungsten-containing precursor and the reducing gas may have different durations. That is the duration of the pulse of the tungsten-containing precursor may be shorter or longer than the duration of the pulse of the reducing gas. For such an embodiment, a time interval (T₁) for the pulse of the tungsten-containing precursor is different than a time interval (T₂) for the pulse of the reducing gas.

In addition, the periods of non-pulsing between each of the pulses of the tungsten-containing precursor and the reducing gas may have the same duration. That is the duration of the period of non-pulsing between each pulse of the tungsten-containing precursor and each pulse of the reducing gas is identical. For such an embodiment, a time interval (T₃) of non-pulsing between the pulse of the tungsten-containing precursor and the pulse of the reducing gas is equal to a time interval (T₄) of non-pulsing between the pulse of the reducing gas and the pulse of the tungsten-containing precursor. During the time periods of non-pulsing only the constant carrier gas stream is provided to the process chamber.

Alternatively, the periods of non-pulsing between each of the pulses of the tungsten-containing precursor and the reducing gas may have different durations. That is the duration of the period of non-pulsing between each pulse of the tungsten-containing precursor and each pulse of the reducing gas may be shorter or longer than the duration of the period of non-pulsing between each pulse of the reducing gas and the tungsten-containing precursor. For such an embodiment, a time interval (T₃) of non-pulsing between the pulse of the tungsten-containing precursor and the pulse of the reducing gas is different from a time interval (T₄) of non-pulsing between the pulse of the reducing gas and the pulse of the tungsten-containing precursor. During the time periods of non-pulsing only the constant carrier gas stream is provided to the process chamber.

Additionally, the time intervals for each pulse of the tungsten-containing precursor, the reducing gas and the periods of non-pulsing therebetween for each deposition cycle may have the same duration. For such an embodiment, a time interval (T₁) for the tungsten-containing precursor, a time interval (T₂) for the reducing gas, a time interval (T₃) of non-pulsing between the pulse of the tungsten-containing precursor and the pulse of the reducing gas and a time interval (T₄) of non-pulsing between the pulse of the reducing gas and the pulse of the tungsten-containing precursor each have the same value for each deposition cycle. For example, in a first deposition cycle (C₁), a time interval (T₁) for the pulse of the tungsten-containing precursor has the same duration as the time interval (T₁) for the pulse of the tungsten-containing precursor in a second deposition cycle (C₂). Similarly, the duration of each pulse of the reducing gas and the periods of non-pulsing between the pulse of the tungsten-containing precursor and the reducing gas in deposition cycle (C₁) is the same as the duration of each pulse of the reducing gas and the periods of non-pulsing between the pulse of the tungsten-containing precursor and the reducing gas in deposition cycle (C₂), respectively.

Additionally, the time intervals for at least one pulse of the tungsten-containing precursor, the reducing gas and the periods of non-pulsing therebetween for one or more of the deposition cycles of the tungsten deposition process may have different durations. For such an embodiment, one or more of the time intervals (T₁) for the pulses of the tungsten-containing precursor, the time intervals (T₂) for the pulses of the reducing gas, the time intervals (T₃) of non-pulsing between the pulse of the tungsten-containing precursor and the pulse of the reducing gas and the time intervals (T₄) of non-pulsing between the pulse of the reducing gas and the pulse of the tungsten-containing precursor may have different values for one or more deposition cycles of the tungsten deposition process. For example, in a first deposition cycle (C₁), the time interval (T₁) for the pulse of the tungsten-containing precursor may be longer or shorter than the time interval (T₁) for the pulse of the tungsten-containing precursor in a second deposition cycle (C₂). Similarly, the duration of each pulse of the reducing gas and the periods of non-pulsing between the pulse of the tungsten-containing precursor and the reducing gas in deposition cycle (C₁) may be the same or different than the duration of each pulse of the reducing gas and the periods of non-pulsing between the pulse of the tungsten-containing precursor and the reducing gas in deposition cycle (C₂), respectively.

Referring to step 110, after each deposition cycle (steps 104 through 108) a thickness of tungsten will be formed on the substrate. Depending on specific device requirements, subsequent deposition cycles may be needed to achieve a desired thickness. As such, steps 104 through 108 are repeated until the desired thickness for the tungsten layer is achieved. Thereafter, when the desired thickness for the tungsten layer is achieved the process is stopped as indicated by step 112.

In an alternate process sequence described with respect to FIG. 4, the tungsten deposition cycle comprises separate pulses for each of the tungsten-containing precursor, the reducing gas and the purge gas. For such an embodiment, a tungsten layer deposition sequence 200 includes providing a substrate to the process chamber (step 202), providing a first pulse of a purge gas to the process chamber (step 204), providing a pulse of a tungsten-containing precursor to the process chamber (step 206), providing a second pulse of the purge gas to the process chamber (step 208), providing a pulse of a reducing gas to the process chamber (step 210), and then repeating steps 204 through 208 or stopping the deposition process (step 214) depending on whether a desired thickness for the tungsten layer has been achieved.

The time intervals for each of the pulses of the tungsten-containing precursor, the reducing gas and the purge gas may have the same or different durations as discussed above with respect to FIG. 3. Alternatively, the time intervals for at least one pulse of the tungsten-containing precursor, the purge gas for one or more of the deposition cycles of the tungsten deposition process may have different durations.

In FIGS. 3-4, the tungsten deposition cycle is depicted as beginning with a pulse of the tungsten-containing precursor followed by a pulse of the reducing gas. Alternatively, the tungsten deposition cycle may start with a pulse of the reducing gas followed by a pulse of the tungsten-containing precursor.

The tungsten layer may comprise for example, tungsten (W), tungsten boride (W₂B), or tungsten nitride (WN). Suitable tungsten-containing precursors for forming such tungsten layers may include for example tungsten hexafluoride (WF₆) and tungsten carbonyl (W(CO)₆), among others. Suitable reducing gases may include, for example, ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), silane (SiH₄), disilane (Si₂H₆), dichlorosilane (SiCl₂H₂), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀), among others.

One exemplary process of depositing a tungsten layer comprises sequentially providing pulses of tungsten hexafluoride (WF₆) and pulses of diborane (B₂H₆). The tungsten hexafluoride (WF₆) may be provided to an appropriate flow control valve, for example, an electronic control valve, at a flow rate of between about 10 sccm (standard cubic centimeters per minute) and about 400 sccm, preferably between about 20 sccm and about 100 sccm, and thereafter pulsed for about 1 second or less, preferably about 0.2 seconds or less. A carrier gas comprising argon is provided along with the tungsten hexafluoride at a flow rate between about 250 sccm to about 1000 sccm, preferably between about 500 sccm to about 750 sccm. The diborane (B₂H₆) may be provided to an appropriate flow control valve, for example, an electronic control valve, at a flow rate of between about 5 sccm and about 150 sccm, preferably between about 5 sccm and about 25 sccm, and thereafter pulsed for about 1 second or less, preferably about 0.2 seconds or less. A carrier gas comprising argon is provided along with the diborane at a flow rate between about 250 sccm to about 1000 sccm, preferably between about 500 sccm to about 750 sccm. The substrate may be maintained at a temperature between about 250° C. to about 350°0 C. at a chamber pressure between about 1 torr to about 10 torr.

Another exemplary process of depositing a tungsten layer comprises sequentially providing pulses of tungsten hexafluoride (WF₆) and pulses of silane (SiH₄). The tungsten hexafluoride (WF₆) may be provided to an appropriate flow control valve, for example, an electronic control valve, at a flow rate of between about 10 sccm (standard cubic centimeters per minute) and about 400 sccm, preferably between about 20 sccm and about 100 sccm, and thereafter pulsed for about 1 second or less, preferably about 0.2 seconds or less. A carrier gas comprising argon is provided along with the tungsten hexafluoride at a flow rate between about 250 sccm to about 1000 sccm, preferably between about 300 sccm to about 500 sccm. The silane (SiH₄) may be provided to an appropriate flow control valve, for example, an electronic control valve, at a flow rate of between about 10 sccm to about 500 sccm, preferably between about 50 sccm to about 200 sccm, and thereafter pulsed for about 1 second or less, preferably about 0.2 seconds or less. A carrier gas comprising argon is provided along with the silane at a flow rate between about 250 sccm to about 1000 sccm, preferably between about 300 sccm to about 500 sccm. A pulse of a purge gas comprising argon at a flow rate between about 300 sccm to about 1000 sccm, preferably between about 500 sccm to about 750 sccm, in pulses of about 1 second or less, preferably about 0.3 seconds or less is provided between the pulses of the tungsten hexafluoride (WF₆) and the pulses of silane (SiH₄). The substrate may be maintained at a temperature between about 300° C. to about 400° C. at a chamber pressure between about 1 torr to about 10 torr.

Integrated Circuit Fabrication Processes

1. Trench Capacitor

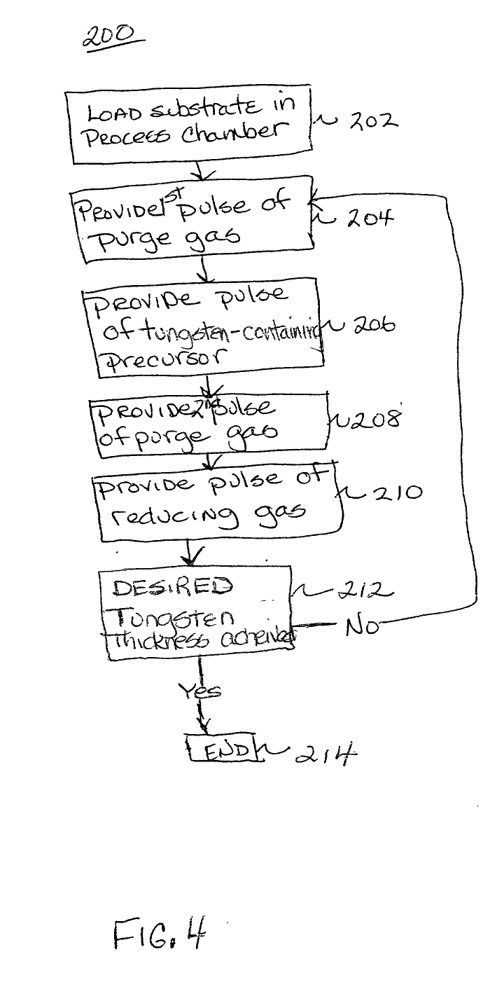

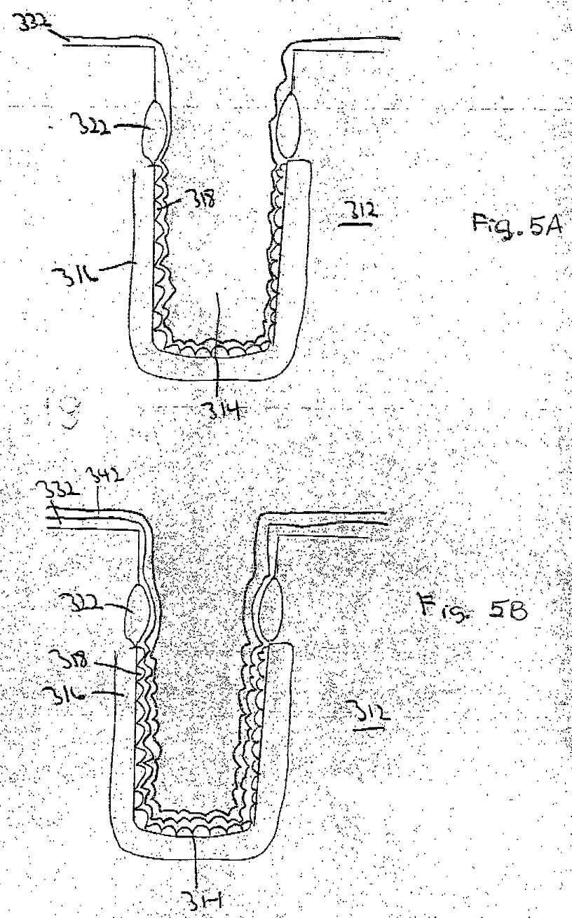

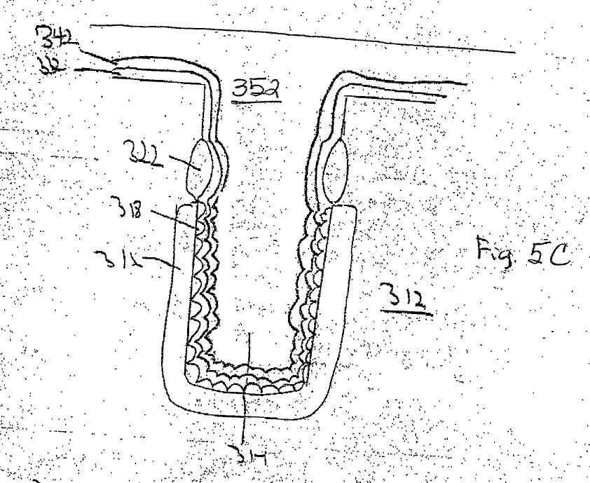

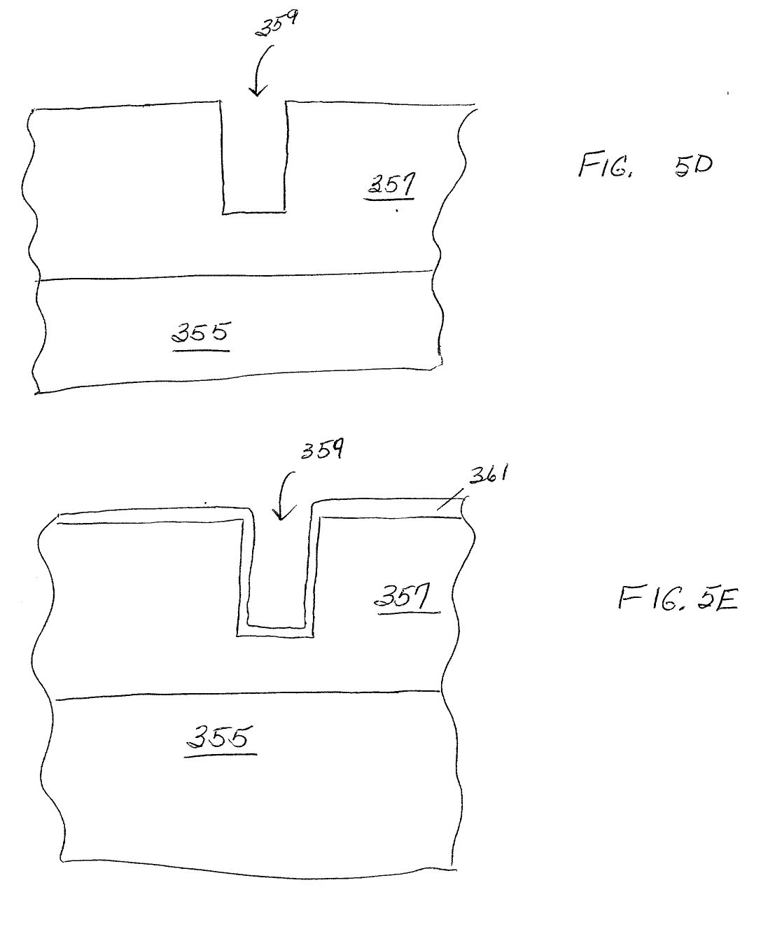

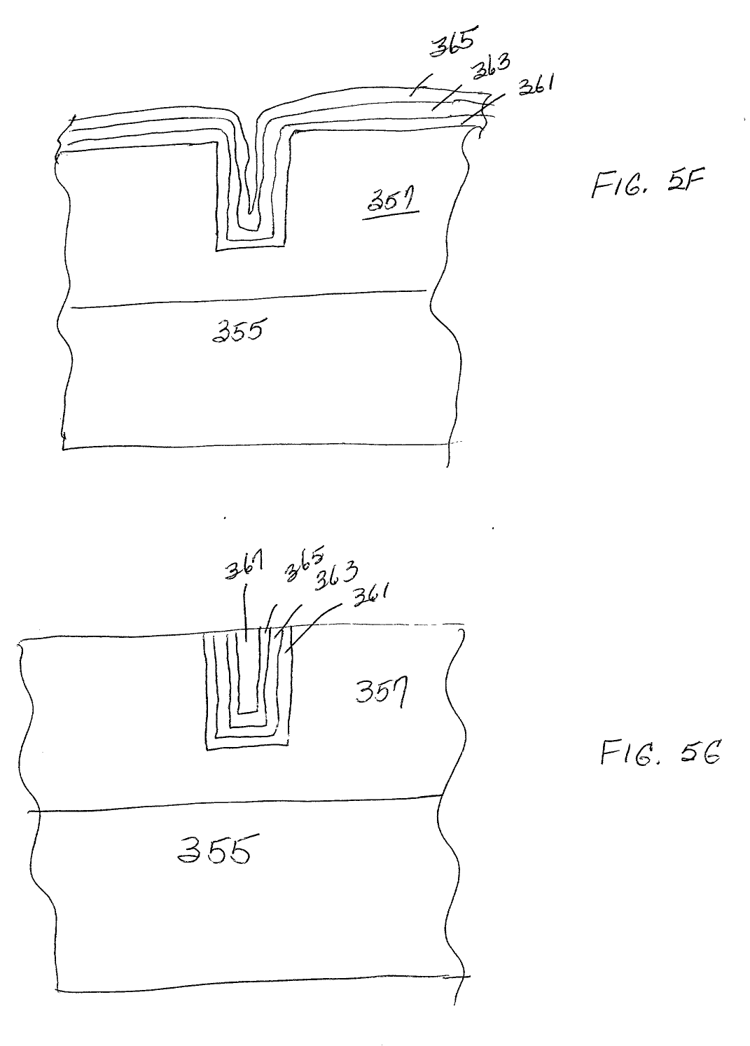

FIGS. 5A-5C illustrate cross-sectional views of a substrate at different stages of a semiconductor-insulator-metal (SIM) trench capacitor fabrication sequence incorporating a tungsten electrode formed using a cyclical deposition process. FIG. 5A, for example, illustrates a cross-sectional view of a substrate 312 having a trench 314 formed therein. The substrate 312 may comprise a semiconductor material such as, for example, silicon (Si), germanium (Ge), or gallium arsenide (GaAs). The trench is formed using conventional lithography and etching techniques.

The bottom and lower sidewalls of the trench 314 may be doped with a suitable dopant to provide a first electrode 316 for the trench capacitor. Suitable dopants may include for example, arsenic (As), antimony (Sb), phosphorous (P) and boron (B), among others.

A collar 322 may be formed along the upper sidewalls of the trench 314 to serve as an insulating layer in the final device structure. The collar 322 typically comprises an insulator such as for example, silicon oxide. A hemispherical silicon grain layer (HSG) 318 or a rough polysilicon layer may optionally be formed over the first electrode 316 to increase the surface area thereof. The hemispherical silicon grain layer 318 may be formed, for example, by depositing an amorphous silicon layer an than annealing it to form a rough surface thereon. The hemispherical silicon grain layer 318 may optionally be doped.

The trench capacitor further includes an insulating layer 332 formed over the collar 322 and hemispherical silicon grain layer 318 in the trench 314. The insulating layer 332 preferably comprises a high dielectric constant material (dielectric constant greater then about 10). High dielectric constant materials advantageously permit higher charge storage capacities for the capacitor structures. Suitable dielectric materials may include for example, tantalum pentoxide (Ta₂O₅), silicon oxide/silicon nitride/oxynitride (ONO), aluminum oxide (Al₂O₃), barium strontium titanate (BST), barium titanate, lead zirconate titanate (PZT), lead lanthanium titanate, strontium titanate and strontium bismuth titanate, among others.

The thickness of the insulating layer 332 is variable depending on the dielectric constant of the material used and the geometry of the device being fabricated. Typically, the insulating layer 332 has a thickness of about 100 Å to about 1000 Å.

Referring to FIG. 5B, a tungsten layer 342 is formed according to the present invention over the insulating layer 332. The tungsten layer 342 comprises the second electrode of the trench capacitor. The tungsten layer 342 is formed using an embodiment of the cyclical deposition technique described above with respect to FIGS. 3-4. The cyclical deposition techniques employed for the tungsten deposition provide conformal coverage along the sidewalls of the trench 314. The thickness of the tungsten layer 342 is typically about 100 Å to about 1000 Å.

After the tungsten layer 342 is formed, the trench capacitor is completed by filling the trench 314 with, for example, a polysilicon layer 352, as shown in FIG. 5C. The polysilicon layer 352 may be formed using conventional deposition techniques. For example, the polysilicon layer 352 may be deposited using a chemical vapor deposition (CVD) process in which silane (SiH₄) is thermally decomposed to form polysilicon at a temperature between about 550° C. and 700° C.

Alternatively, FIGS. 5D-5G are illustrative of a metal-insulator-metal (MIM) trench capacitor fabrication sequence incorporating two tungsten electrodes formed using a cyclical deposition process. FIG. 5D, for example, illustrates a cross-sectional view of a substrate 355 having a dielectric material layer 357 formed therein. The substrate 355 may comprise a semiconductor material such as, for example, silicon (Si), germanium (Ge), or gallium arsenide (GaAs). The dielectric material layer 357 may comprise an insulator such as, for example, silicon oxide or silicon nitride. At least one trench 359 is defined in the dielectric material layer 357. The trench may be formed using conventional lithography and etching techniques.

Referring to FIG. 5E, a tungsten layer 361 is formed according to the present invention over the dielectric material layer 357 in the at least one trench 359. The tungsten layer 361 comprises the first electrode of the metal-insulator-metal (MIM) trench capacitor. The tungsten layer 361 is formed using an embodiment of the cyclical deposition technique described above with respect to FIGS. 3-4. The cyclical deposition techniques employed for the tungsten deposition provide conformal coverage along the sidewalls of the trench 359. The thickness of the tungsten layer 361 is typically about 100 Å to about 1000 Å.

The trench capacitor further includes an insulating layer 363 formed over the tungsten layer 361 comprising the first electrode in the trench 359, as shown in FIG. 5F. The insulating layer 363 preferably comprises a high dielectric constant material (dielectric constant greater then about 10). High dielectric constant materials advantageously permit higher charge storage capacities for the capacitor structures. Suitable dielectric materials may include for example, tantalum pentoxide (Ta₂O₅), silicon oxide/silicon nitride/oxynitride (ONO), aluminum oxide (Al₂O₃), barium strontium titanate (BST), barium titanate, lead zirconate titanate (PZT), lead lanthanium titanate, strontium titanate and strontium bismuth titanate, among others.

The thickness of the insulating layer 363 is variable depending on the dielectric constant of the material used and the geometry of the device being fabricated. Typically, the insulating layer 363 has a thickness of about 100 Å to about 1000 Å.

A tungsten layer 365, deposited according to the present invention, is formed over the insulating layer 363. The tungsten layer 365 comprises the second electrode of the metal-insulator-metal (MIM) trench capacitor. The tungsten layer 365 is formed using an embodiment of the cyclical deposition technique described above with respect to FIGS. 3-4. The cyclical deposition techniques employed for the tungsten deposition provide conformal coverage along the sidewalls of the trench 359. The thickness of the tungsten layer 365 is typically about 100 Å to about 1000 Å.

After the tungsten layer 365 is formed, the metal-insulator-metal (MIM) trench capacitor is completed by filling the trench 359 with, for example, a polysilicon layer 367, as shown in FIG. 5G. The polysilicon layer 367 may be formed using conventional deposition techniques. For example, the polysilicon layer 367 may be deposited using a chemical vapor deposition (CVD) process in which silane (SiH₄) is thermally decomposed to form polysilicon at a temperature between about 550° C. and 700° C.

2. Crown Capacitor

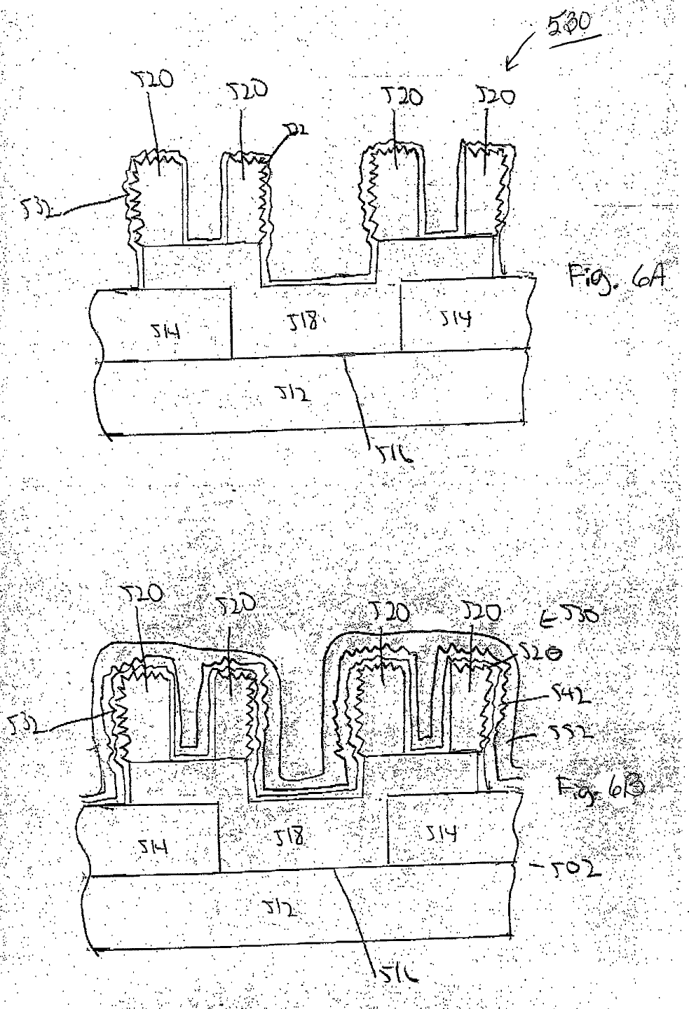

FIGS. 6A-6B illustrate cross-sectional views of a substrate at different stages of a crown capacitor fabrication sequence incorporating a tungsten electrode formed using a cyclical deposition process. The term crown capacitor as used herein refers to a capacitor structure having a three-dimensional shape formed above the surface of the substrate. The three-dimensional shape increases the capacitance of the device by increasing the surface area thereof. FIG. 6A, for example, illustrates a cross-sectional view of a substrate 512 having a dielectric layer 514 formed thereon. The substrate 512 may comprise a semiconductor material such as, for example, silicon (Si), germanium (Ge), or gallium arsenide (GaAs). The dielectric 514 may comprise an oxide such as, for example, a silicon oxide. The dielectric layer 514 has at least one aperture 516 formed therein.

A first polysilicon layer 518 is formed over the dielectric layer 514 and the at least one aperture 516. The first polysilicon layer 518 may be doped with a suitable dopant such as, for example, arsenic (As), antimony (Sb), phosphorous (P) and boron (B), among others.

A hemispherical silicon grain layer (HSG) 520 or a rough polysilicon layer may optionally be formed over the first polysilicon layer 518 to increase the surface area thereof. The hemispherical silicon grain layer 520 may be formed, for example, by depositing an amorphous silicon layer and than annealing it to form a rough surface thereon. The hemispherical silicon grain layer 520 may optionally by doped.

The first polysilicon layer 518 and the hemispherical silicon grain layer (HSG) 520 are patterned and etched to form a crown structure 530. Both the first polysilicon layer 518 and the hemispherical silicon grain layer (HSG) act as a first electrode for the crown capacitor.

The crown capacitor further includes an insulating layer 532 formed over the hemispherical silicon grain layer 518 of the crown structure 530. The insulating layer 532 preferably comprises a high dielectric constant material (dielectric constant greater then about 10). High dielectric constant materials advantageously permit higher charge storage capacities for the capacitor structures. Suitable dielectric materials may include for example, tantalum pentoxide (Ta₂O₅), silicon oxide/silicon nitride/oxynitride (ONO), aluminum oxide (Al₂O₃), barium strontium titanate (BST), barium titanate, lead zirconate titanate (PZT), lead lanthanium titanate, strontium titanate and strontium bismuth titanate, among others.

Referring to FIG. 6B, a tungsten layer 542 is formed over the insulating layer 532. The tungsten layer 542 comprises the second electrode of the crown capacitor. The tungsten layer 542 is formed using the cyclical deposition techniques described above with respect to FIGS. 3-4. The cyclical deposition techniques employed for the tungsten deposition provide conformal coverage along the sidewalls of the crown structure 530.

After the tungsten layer 542 is formed, the crown capacitor is completed by depositing, for example, a second polysilicon layer 552 thereover, as shown in FIG. 6B. The second polysilicon layer 552 may be formed using conventional deposition techniques. For example, the second polysilicon layer 552 may be deposited using a chemical vapor deposition (CVD) process in which silane (SiH₄) is thermally decomposed to form polysilicon at a temperature between about 550° C. and 700° C.

The crown capacitor and trench capacitor structures described herein are illustrative of the advanced capacitor devices that can be fabricated using the techniques of the present invention. Highly conformal and controlled deposition of the tungsten layers enable even more advanced dynamic random access memory (DRAM) devices to be fabricated.

Moreover capacitor enhancing techniques that increase the surface area of a given capacitor structure may also be used in combination with embodiments described herein. For example, providing a rough polysilicon or hemispherical grained surface on sidewalls of a trench structure which may be conformably covered with a tungsten layer as described herein advantageously provide a capacitor structure with increased surface area.

While foregoing is directed to the preferred embodiment of the present invention, other and further embodiments of the invention may be devised without departing from the basic scope thereof, and the scope thereof is determined by the claims that follow.

What is claimed is:

1. A method of forming an electrode for a capacitor structure, comprising:
providing a substrate structure, wherein the substrate structure comprises an insulating material layer formed over a first electrode;
depositing a tungsten-based layer on the insulating material layer using a cyclical deposition process, wherein the tungsten-based layer comprises a second electrode.

2. The method of claim 1 wherein the cyclical deposition process comprises alternately adsorbing monolayers of a tungsten-containing precursor and a reducing gas on the insulating material layer.

3. The method of claim 1 wherein the tungsten-based layer comprises a material selected from the group consisting of tungsten (W), tungsten boride (W₂B) and tungsten nitride (WN).

4. The method of claim 2 wherein the tungsten-containing precursor is selected from the group consisting of tungsten hexafluoride (WF₆) and tungsten carbonyl (W(CO)₆).

5. The method of claim 2 wherein the reducing gas is selected from the group consisting of ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), silane (SiH₄), disilane (Si₂H₆), dichlorosilane (SiCl₂H₂), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀), and combinations thereof.

6. The method of claim 1 wherein the substrate structure is a trench structure.

7. The method of claim 1 wherein the substrate structure is a crown structure.

8. The method of claim 1 wherein the insulating material comprises a material selected from the group consisting of tantalum pentoxide (Ta₂O₅), silicon oxide/silicon nitride/oxynitride (ONO), aluminum oxide (Al₂O₃), barium strontium titanate (BST), barium titanate, lead zirconate titanate (PZT), lead lanthanium titanate, strontium titanate and strontium bismuth titanate.

9. The method of claim 1 wherein the first electrode comprises polysilicon.

10. The method of claim 1 wherein the first electrode comprises a tungsten-based layer formed using a cyclical deposition process.

11. A method of forming a capacitor structure, comprising:
forming a first electrode on a substrate;
forming an insulating material layer over the first electrode; and
depositing a tungsten-based layer on the insulating material layer using a cyclical deposition process, wherein the tungsten-based layer comprises a second electrode.

12. The method of claim 11 wherein the cyclical deposition process comprises alternately adsorbing monolayers of a tungsten-containing precursor and a reducing gas on the insulating material layer.

13. The method of claim 11 wherein the tungsten-based layer comprises a material selected from the group consisting of tungsten (W), tungsten boride (W₂B) and tungsten nitride (WN).

14. The method of claim 12 wherein the tungsten-containing precursor is selected from the group consisting of tungsten hexafluoride (WF₆) and tungsten carbonyl (W(CO)₆).

15. The method of claims 12 wherein the reducing gas is selected from the group consisting of ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), silane (SiH₄), disilane (Si₂H₆), dichlorosilane (SiCl₂H₂), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀), and combinations thereof.

16. The method of claim 11 wherein the capacitor structure is a trench structure.

17. The method of claim 11 wherein the capacitor structure is a crown structure.

18. The method of claim 11 wherein the insulating material comprises a material selected from the group consisting of tantalum pentoxide (Ta₂O₅), silicon oxide/silicon nitride/oxynitride (ONO), aluminum oxide (Al₂O₃), barium strontium titanate (BST), barium titanate, lead zirconate titanate (PZT), lead lanthanium titanate, strontium titanate and strontium bismuth titanate.

19. The method of claim 11 wherein the first electrode comprises polysilicon.

20. The method of claim 11 wherein the first electrode comprises a tungsten-based layer formed using a cyclical deposition process.

21. A method of forming an electrode, comprising:
providing a substrate to a process chamber; and
depositing a tungsten-based layer on the substrate using a cyclical deposition process comprising a plurality of cycles, wherein each cycle comprises establishing a flow of an inert gas to the process chamber and modulating the flow of the inert gas with an alternating period of exposure to one of either a tungsten-containing precursor and a reducing gas.

22. The method of claim 21 wherein the period of exposure to the tungsten-containing precursor, the period of exposure to the reducing gas, a period of flow of the inert gas between the period of exposure to the tungsten-containing precursor and the period of exposure to the reducing gas, and a period of flow of the inert gas between the period of exposure to the reducing gas and the period of exposure to the tungsten-containing precursor each have the same duration.

23. The method of claim 21 wherein at least one of the period of exposure to the tungsten-containing precursor, the period of exposure to the reducing gas, a period of flow of the inert gas between the period of exposure to the tungsten-containing precursor and the period of exposure to the reducing gas, and a period of flow of the inert gas between the period of exposure to the reducing gas and the period of exposure to the tungsten-containing precursor has a different duration.

24. The method of claim 21 wherein the period of exposure to the tungsten-containing precursor during each deposition cycle of the cyclical deposition process has the same duration.

25. The method of claim 21 wherein at least one period of exposure to the tungsten-containing precursor for one or more deposition cycle of the cyclical deposition process has a different duration.

26. The method of claim 21 wherein the period of exposure to the reducing gas during each deposition cycle of the cyclical deposition process has the same duration.

27. The method of claim 21 wherein at least one period of exposure to the reducing gas for one or more deposition cycle of the cyclical deposition process has a different duration.

28. The method of claim 21 wherein a period of flow of the inert gas between the period of exposure to the tungsten-containing precursor and the period of exposure to the reducing gas during each deposition cycle of the cyclical deposition process has the same duration.

29. The method of claim 21 wherein at least one period of flow of the inert gas between the period of exposure to the tungsten-containing precursor and the period of exposure to the reducing gas for one or more deposition cycle of the cyclical deposition process has a different duration.

30. The method of claim 21 wherein a period of flow of the inert gas between the period of exposure to the reducing gas and the period of exposure to the tungsten-containing precursor during each deposition cycle of the cyclical deposition process has the same duration.

31. The method of claim 21 wherein at least one period of flow of the inert gas between the period of exposure to the reducing gas and the period of exposure to the tungsten-containing precursor for one or more deposition cycle of the cyclical deposition process has a different duration.

32. The method of claim 21 wherein the tungsten-containing precursor is selected from the group consisting of tungsten hexafluoride (WF₆) and tungsten carbonyl (W(CO)₆).

33. The method of claims 21 wherein the reducing gas is selected from the group consisting of ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), silane (SiH₄), disilane (Si₂H₆), dichlorosilane (SiCl₂H₂), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀), and combinations thereof.

34. The method of claim 21 wherein the tungsten-based layer comprises a material selected from the group consisting of tungsten (W), tungsten boride (W₂B) and tungsten nitride (WN).

35. A method of forming an electrode for a capacitor structure, comprising:
providing a substrate structure to a process chamber, wherein the substrate structure comprises an insulating material layer formed over a first electrode; and
depositing a tungsten-based layer on the substrate using a cyclical deposition process comprising a plurality of cycles, wherein each cycle comprises establishing a flow of an inert gas to the process chamber and modulating the flow of the inert gas with an alternating period of exposure to one of either a tungsten-containing precursor and a reducing gas, and wherein the tungsten-based layer comprises a second electrode.

36. The method of claim 35 wherein the period of exposure to the tungsten-containing precursor, the period of exposure to the reducing gas, a period of flow of the inert gas between the period of exposure to the tungsten-containing precursor and the period of exposure to the reducing gas, and a period of flow of the inert gas between the period of exposure to the reducing gas and the period of exposure to the tungsten-containing precursor each have the same duration.

37. The method of claim 35 wherein at least one of the period of exposure to the tungsten-containing precursor, the period of exposure to the reducing gas, a period of flow of the inert gas between the period of exposure to the tungsten-containing precursor and the period of exposure to the reducing gas, and a period of flow of the inert gas between the period of exposure to the reducing gas and the period of exposure to the tungsten-containing precursor has a different duration.

38. The method of claim 35 wherein the period of exposure to the tungsten-containing precursor during each deposition cycle of the cyclical deposition process has the same duration.

39. The method of claim 35 wherein at least one period of exposure to the tungsten-containing precursor for one or more deposition cycle of the cyclical deposition process has a different duration.

40. The method of claim 35 wherein the period of exposure to the reducing gas during each deposition cycle of the cyclical deposition process has the same duration.

41. The method of claim 35 wherein at least one period of exposure to the reducing gas for one or more deposition cycle of the cyclical deposition process has a different duration.

42. The method of claim 35 wherein a period of flow of the inert gas between the period of exposure to the tungsten-containing precursor and the period of exposure to the reducing gas during each deposition cycle of the cyclical deposition process has the same duration.

43. The method of claim 35 wherein at least one period of flow of the inert gas between the period of exposure to the tungsten-containing precursor and the period of exposure to the reducing gas for one or more deposition cycle of the cyclical deposition process has a different duration.

44. The method of claim 35 wherein a period of flow of the inert gas between the period of exposure to the reducing gas and the period of exposure to the tungsten-containing precursor during each deposition cycle of the cyclical deposition process has the same duration.

45. The method of claim 35 wherein at least one period of flow of the inert gas between the period of exposure to the reducing gas and the period of exposure to the tungsten-containing precursor for one or more deposition cycle of the cyclical deposition process has a different duration.

46. The method of claim 35 wherein the tungsten-containing precursor is selected from the group consisting of tungsten hexafluoride (WF₆) and tungsten carbonyl (W(CO)₆).

47. The method of claims 35 wherein the reducing gas is selected from the group consisting of ammonia (NH₃), hydrazine (N₂H₄), monomethyl hydrazine (CH₃N₂H₃), dimethyl hydrazine (C₂H₆N₂H₂), t-butyl hydrazine (C₄H₉N₂H₃), phenyl hydrazine (C₆H₅N₂H₃), 2,2′-azoisobutane ((CH₃)₆C₂N₂), ethylazide (C₂H₅N₃), silane (SiH₄), disilane (Si₂H₆), dichlorosilane (SiCl₂H₂), borane (BH₃), diborane (B₂H₆), triborane (B₃H₉), tetraborane (B₄H₁₂), pentaborane (B₅H₁₅), hexaborane (B₆H₁₈), heptaborane (B₇H₂₁), octaborane (B₈H₂₄), nanoborane (B₉H₂₇) and decaborane (B₁₀H₃₀), and combinations thereof.

48. The method of claim 35 wherein the tungsten-based layer comprises a material selected from the group consisting of tungsten (W), tungsten boride (W₂B) and tungsten nitride (WN).

49. The method of claim 35 wherein the capacitor structure is a trench structure.

50. The method of claim 35 wherein the capacitor structure is a crown structure.

51. The method of claim 35 wherein the insulating material comprises a material selected from the group consisting of tantalum pentoxide (Ta₂O₅), silicon oxide/silicon nitride/oxynitride (ONO), aluminum oxide (Al₂O₃), barium strontium titanate (BST), barium titanate, lead zirconate titanate (PZT), lead lanthanium titanate, strontium titanate and strontium bismuth titanate.

52. The method of claim 35 wherein the first electrode comprises polysilicon.

53. The method of claim 35 wherein the first electrode comprises a tungsten-based layer formed using a cyclical deposition process.
